(19) United States
(12) Patent Application Publication
(10) Pub. No.: US 2006/0216935 A1
(43) Pub. Date: Sep. 28, 2006

(54) Composition for oxide CMP in CMOS device fabrication

(75) Inventors: Eric S. Oswald, Rochester, NY (US); Yue Liu, Pittsford, NY (US)

Correspondence Address: RANKIN, HILL, PORTER & CLARK, LLP, 925 EUCLID AVENUE, SUITE 700, CLEVELAND, OH, 44115-1405, US

(73) Assignee: Ferro Corporation, Cleveland, OH (US)

(21) Appl. No.: 11/091,691

(22) Filed: Mar. 28, 2005

(51) Int. Cl. H01L 21/336; H01L 21/302; H01L 21/461

(52) U.S. Cl. 438/691; 438/296

(57) ABSTRACT

The present invention provides an oxide CMP slurry composition for use in planarizing silicon oxide-containing films via CMP during CMOS device fabrication, and a method of planarizing silicon oxide-containing films via CMP using the slurry composition. The oxide CMP slurry composition according to the invention includes: (i) proline, lysine and/or arginine; (ii) a pyrrolidone compound; and (iii) abrasive particles. Proline is presently most preferred for use in the invention. In the STI sub-process of the CMOS device fabrication process, the oxide CMP slurry composition according to the present invention acts to aggressively remove only the silicon dioxide overburden on the processed wafer that is in contact with a polishing pad, which results in the formation of a substantially planar, defect-free surface. The oxide CMP slurry composition according to the invention does not aggressively remove trench silicon dioxide thereby allowing for extended polishing beyond the end point without substantially increasing the minimum step height.

### BACKGROUND OF THE INVENTION

1. Field of Invention

The present invention relates to a composition for use in planarizing oxide films via chemical-mechanical polishing during complimentary metal-oxide-semiconductor (“CMOS”) device fabrication.

2. Description of Related Art

Chapter 9 of the Advanced Semiconductor Fabrication Handbook authored by Lita Shon-Roy et al. (copyright 1998 by Integrated Circuit Engineering Corporation), which is hereby incorporated by reference in its entirety, provides a step-by-step description of the basic CMOS device fabrication process. Several of the steps of the CMOS device process involve the planarization of silicon oxide-containing films via chemical-mechanical polishing (“CMP”).

For example, in Step 22 of the incorporated reference, the portion of a film of chemical-vapor deposited silicon oxide (“CVD Oxide”) residing above a plane defined by a top surface of an underlying, patterned silicon nitride layer is removed by CMP. In this oxide CMP step, the underlying silicon nitride serves as a “CMP-stop” layer that resists polishing once the overlying CVD Oxide has been removed. This oxide CMP step is part of a sub-process of the CMOS fabrication process known in the art as the shallow trench isolation (“STI”) process. A more thorough explanation of the STI sub-process is set forth on pages 9-5 through 9-8 of the incorporated reference.

FIG. 1 attached hereto is an exemplary schematic side sectional view of a CMOS device prior to the oxide CMP step in the STI sub-process. A silicon wafer serves as a substrate 1. An oxide layer 2 having a thickness of about 100-200 Å is grown on the substrate 1 using a thermal oxidation furnace. The oxide layer 2 serves as a buffer between the substrate 1 and a patterned stop layer of silicon nitride 3. The silicon nitride stop layer 3 is typically about 1000-2500 Å thick and is typically deposited on top of the oxide layer 2 using chemical vapor deposition (CVD) or low-pressure CVD technology. The silicon nitride stop layer 3 is patterned using a photo-resist and etching process. Etching forms a trench that passes through the silicon nitride stop layer 3, the underlying oxide layer 2 and into the substrate 1. The depth of the trench is typically about 5000 Å measured from the plane defined by the top surface of the patterned silicon nitride stop layer 3 to the bottom of the trench. The silicon nitride stop layer 3 defines the active areas where transistor gates, sources and drains will be formed by later process steps. The trench is filled with silicon dioxide 4, typically using CVD technology, which serves as an isolating dielectric field area.

During the deposition of the silicon dioxide 4, the trench is filled, but silicon dioxide also covers the silicon nitride stop layer 3 creating a silicon dioxide overburden 5 that must be removed by oxide CMP. The difference in height between the top of the silicon dioxide overburden 5 covering the silicon nitride stop layer 3 and the top of the silicon dioxide 6 filling the trench is referred to the “pre-CMP step height”.

A polishing composition that assists in selectively removing silicon dioxide in preference to silicon nitride is applied between a polishing pad and the surface of the processed wafer while the polishing pad and processed wafer are in motion relative to each other. Ideally, the oxide CMP step removes all of the silicon dioxide overburden 5 covering the silicon nitride stop layer 3 without removing the silicon dioxide filling the trench below a plane defined by the top surface of the silicon nitride stop layer 3. FIG. 2 shows an exemplary schematic side sectional view of a CMOS device after the oxide CMP step in the STI sub-process. The difference in height between the plane defined by the top surface of the silicon nitride stop layer 3 and the top of the silicon dioxide in the trench is referred to as the “post-CMP step height”. The post-CMP step height is preferably minimal, and ideally is zero (i.e., the wafer is completely planar after the oxide CMP). Once all of the silicon dioxide overburden 5 has been removed and the surface of the processed wafer has been sufficiently planarized by oxide CMP, the silicon nitride stop layer 3 is removed, leaving trenches that are filled with silicon oxide (field areas) and clear areas between them for subsequent transistor formation (active areas).

The polishing composition used during the oxide CMP step in the STI sub-process is an important factor in determining the rate at which the silicon dioxide overburden 5 is removed. If the chemical agents in the polishing composition are selected properly, the polishing composition can provide rapid and effective removal of the silicon dioxide overburden 5 while minimizing the formation or creation of surface imperfections or defects, particularly in the silicon dioxide filling the trench.

In an ideal CMP process, a completely smooth and level (i.e., planar) surface is created on the processed wafer, meaning that all of the silicon dioxide overburden has been removed and there is no step height difference between the top of the silicon nitride stop layer 3 and the surface of the silicon dioxide filling the trench. However, in practice, this has been very difficult to achieve. In most instances, during removal of the silicon dioxide overburden 5, there is some unwanted removal of the silicon dioxide filling the trench, which creates a “dishing” defect in the final processed wafer. The “dishing” defect is particularly problematic when polishing continues past the point in time when all of the silicon dioxide overburden 5 has been removed from the silicon nitride stop layer 3. This moment in time is referred to in the art as the “end point”. Prior art oxide CMP polishing compositions tend to continue to aggressively remove the silicon dioxide filling the trench when CMP continues beyond the end point, even if the continued polishing lasts only for a few seconds.

To compensate for the difficulties in achieving planarity, relatively thick silicon dioxide layers can be applied. This is disadvantageous in that it requires that more silicon dioxide be removed by oxide CMP, which extends the polishing time and wastes material. Alternatively, the oxide CMP step can be subjected to extremely accurate end point polishing determinations. In prior art CMP processes, polishing beyond the end point for even a few seconds tends to dish out and remove the silicon dioxide in the trench, resulting in an undesired increase from the minimum step height. But monitoring and effectively controlling the polishing end point is difficult, particularly on larger wafers. Therefore, there remains a need for a polishing composition and method that does not increase the minimum step height during extended polishing beyond the end point.

### BRIEF SUMMARY OF THE INVENTION

The present invention provides an oxide CMP slurry composition for use in planarizing silicon oxide-containing films via CMP during CMOS device fabrication, and a method of planarizing silicon oxide-containing films via CMP using the slurry composition. The oxide CMP slurry composition according to the invention comprises: (i) proline, lysine and/or arginine; (ii) a pyrrolidone compound; and (iii) abrasive particles. Proline is presently most preferred for use in the invention. In the STI sub-process of the CMOS device fabrication process, the oxide CMP slurry composition according to the present invention acts to aggressively remove only the silicon dioxide overburden on the processed wafer that is in contact with a polishing pad, which results in the formation of a substantially planar, defect-free surface. The oxide CMP slurry composition according to the invention does not aggressively remove trench silicon dioxide thereby allowing for extended polishing beyond the end point without substantially increasing the minimum step height.

The foregoing and other features of the invention are hereinafter more fully described and particularly pointed out in the claims, the following description setting forth in detail certain illustrative embodiments of the invention, these being indicative, however, of but a few of the various ways in which the principles of the present invention may be employed.

### BRIEF DESCRIPTION OF THE DRAWINGS

FIG. 1 is an exemplary schematic side sectional view of a CMOS device prior to the oxide CMP step in the STI sub-process.

FIG. 2 is an exemplary schematic side sectional view of a CMOS device after the oxide CMP step in the STI sub-process.

### DETAILED DESCRIPTION OF THE INVENTION

An oxide CMP slurry composition according to the invention comprises: (i) proline, lysine and/or arginine; (ii) a pyrrolidone compound; and (iii) ceria abrasive particles, which may be dispersed in a liquid medium or bonded to a polishing pad to be dispersed into a liquid medium during polishing. The oxide CMP slurry composition according to the invention can be used to rapidly remove silicon oxide-containing films at any stage of the CMOS device fabrication process, but is particularly suitable for use in removing the silicon dioxide overburden deposited on a silicon nitride stop layer by oxide CMP in the STI sub-process of the CMOS device fabrication process. When disposed between the silicon dioxide overburden and a polishing pad, the oxide CMP slurry composition according to the invention rapidly assists in the removal of the silicon dioxide overburden that is in contact with the polishing pad, but does not aggressively polish the underlying silicon nitride stop layer and does not rapidly remove trench silicon dioxide. Thus, the oxide CMP slurry composition according to the invention has excellent silicon dioxide to silicon nitride selectivity and allows for extended polishing beyond the end point without increasing the minimum step height.

As noted, the oxide CMP slurry composition according to the present invention preferably comprises one or more selected from the group consisting of proline, lysine and arginine. Proline is presently most preferred for use in the invention. The oxide CMP slurry composition preferably comprises from about 0.2% to about 8% by weight of proline, lysine and/or arginine. More preferably, the oxide CMP slurry composition preferably comprises from about 0.5% by weight to about 4% by weight of proline, lysine and/or arginine.

The oxide CMP slurry composition also further comprises a pyrrolidone compound. Suitable pyrrolidone compounds include, for example, polyvinyl pyrrolidone (“PVP”), N-octyl-2-pyrrolidone, N-dodecyl-2-pyrrolidone, N-methyl-2-pyrrolidone, N-ethyl-2-pyrrolidone, N-hydroxyethyl-2-pyrrolidone, N-Cyclohexyl-2-pyrrolidone, N-butyl-2-pyrrolidone, N-hexyl-2-pyrrolidone, N-decyl-2-pyrrolidone, N-octadecyl-2-pyrrolidone, N-hexadecyl-2-pyrrolidone and copolymers of PVP. Preferably the oxide CMP slurry composition comprises from about 0.01% to about 10% of a pyrrolidone compound by weight, and more preferably from about 0.02% to about 5% of a pyrrolidone compound by weight. Applicants have discovered that when a non-polymeric pyrrolidone compound is used (e.g., N-octyl-2-pyrrolidone), the loading of the pyrrolidone compound need not be as great as when a polymeric pyrrolidone compound is used to obtain the desired synergistic trench oxide protection effect. The preferred loading for non-polymeric pyrrolidones is from about 0.02% to about 0.4% by weight, whereas the preferred loading for polymeric pyrrolidones is 0.2% to about 2.0% by weight.

Use of pyrrolidone compound in combination with proline, lysine and/or arginine produces a synergistic effect whereby trench silicon dioxide is not rapidly removed during polishing beyond the end point. This synergistic effect is most pronounced when proline is used. Thus, the minimum step height obtained via oxide CMP can be maintained for extended periods of polishing beyond the end point through the use of an oxide CMP slurry composition according to the invention.

The oxide CMP slurry composition according to the present invention preferably further comprises abrasive particles. The abrasive particles are preferably dispersed in a liquid medium such as water. Alternatively, some or all of the abrasive particles may be affixed to a polishing pad, which releases the abrasive particles into a liquid medium during polishing. Abrasive oxide particles comprising cerium atoms are presently most preferred for use in the invention, but other abrasive particles can alternatively be used. For example, iron oxide or other oxides, carbides or nitrides that are compatible with the other components of the slurry and that provide sufficient polishing rate and performance can also be used.

Titania abrasive particles can be used in combination with ceria abrasive particles. Composite abrasive particles comprising oxides having both cerium atoms and titanium atoms can also be used. Some commonly used CMP abrasives such as alumina and silica are not preferred for use in the oxide CMP slurry composition according to the invention. Alumina, for example, polishes silicon dioxide at a very low rate. Furthermore, proline, lysine and/or arginine tend to become absorbed on the surface of silica, making it unavailable to protect the trench silicon dioxide on the processed wafer. It may be possible to use alumina or silica abrasive particles if such particles are coated with a chemical agent that either improves the removal rate of silicon dioxide or that prevents the absorption of the proline, lysine and/or arginine.

The loading of the abrasive particles in the oxide CMP slurry composition is not per se critical, and thus any effective loading can be utilized. Typically, when ceria abrasive particles are used, the loading of such particles will comprise from about 0.1% to about 15% by weight of the oxide CMP slurry composition at the time of use.

The abrasive particles used in the oxide CMP slurry composition of the invention preferably have a mean secondary particle size (Dₘₑₐₙ) of from about 0.01 microns to about 1.0 μm, and more preferably from about 0.03 to about 0.3 μm. In a most preferred embodiment, the abrasive particles have a mean secondary particle size of about 130 nm. The term “mean secondary particle size” as used herein refers to the average diameter of the particles, which typically consist of agglomerations or aggregations of a plurality of primary particles (“crystallites”).

The oxide CMP slurry composition according to the invention may further comprise one or more optional additives such as dispersing agents, preservative biocides, preservative fungicides, acids bases and/or buffers for pH adjustment. Suitable dispersing agents include polyacrylic acids and salts thereof, carboxylic acids and salts thereof and glycols and polyglycols, which may be present at a loading of from about 0.1% to about 5% by weight of the slurry. A suitable preservative biocide and/or preservative fungicide is glutaraldehyde, which may be present at a loading of from about 0.01% to about 2.0% by weight the slurry.

The pH of the oxide CMP slurry composition according to the invention is preferably less than about 7, and more preferably is adjusted using an acid to be between about 3 and about 5. Nitric acid is preferred for use in adjusting the pH of the oxide CMP slurry composition. An aqueous medium is preferably used, but other polar solvents such as alcohols can be used, if desired.

It will be appreciated that the oxide CMP slurry composition according to the present invention can be used in other oxide CMP processes utilized in CMOS device fabrication process in addition to the STI sub-process. For example, the oxide CMP slurry composition can be used to planarize borophosphosilicate glass (“BPSG”) films, such as is described in Step 58 in the incorporated reference. In addition, the composition according to the invention can be used to planarize plasma-enhanced chemical vapor deposition silicon oxide (“PECVD oxide”) film layers via CMP to form an inter-layer dielectric (“ILD”) layers that reside between layers of aluminum metal lines, such as is described in Step 79, of the incorporated reference. This oxide CMP step is part of a sub-process of the CMOS fabrication process known in the art as the ILD process, and it may be repeated multiple times during the fabrication of a CMOS device (see, e.g., Steps 93, 106 and 119). In addition, the oxide CMP slurry composition according to the invention can be used to polish other materials such as, for example, spin-on glass, carbon-doped oxide and organic low-k dielectric materials.

In order to fairly compare the results provided by the oxide CMP slurry composition according to the present invention with the results provided by other oxide CMP slurry compositions, a standard testing method was developed. Throughout the instant specification and in the appended claims, the phrase “Standard Oxide CMP Testing Method” refers to the following:

### Standard Oxide CMP Testing Method

1. Definitions

(a) Definition of “Step Height”—The difference in height between the highest point on the surface of active areas and the lowest point on the surface of the silicon dioxide in the field area (i.e., the lowest point on the trench silicon dioxide);

(b) Definition of “Pre-CMP Step Height”—The difference in height between the highest point on the surface of active areas and the lowest point on the surface of the silicon dioxide in the field area (i.e., the lowest point on the trench silicon dioxide) before any polishing is conducted, wherein the Pre-CMP Step Height is about 6,000 Å;

(c) Definition of “End Point”—The point in time during polishing at which the “Step Height” between the field areas and the active areas reaches its minimum, with the minimum being no greater than 1,000 Å;

(d) Definition of “Minimum Step Height”—The difference in height between the highest point on the surface of active areas and the lowest point on the surface of the silicon dioxide in the field area (i.e., the lowest point on the trench silicon dioxide) at the End Point; and

(e) Definition of “Over Polishing”—The period of time during which polishing continues beyond the “End Point”.

2. Standard Testing Materials and Equipment:

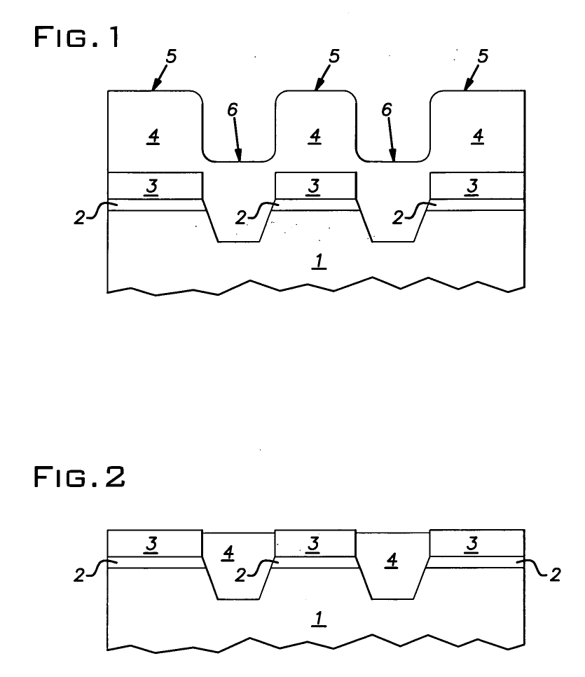

(a) Wafer: an 8-inch silicon wafer having a 100 Å thick thermal oxide layer grown thereon and an 1500 Å thick CVD silicon nitride stop layer formed on the oxide layer, wherein the silicon nitride stop layer, thermal oxide and silicon wafer has been patterned using a photoresist and etch back process to define 100 μm wide field areas (trenches) and 100 μm wide active areas, and wherein the surface of the processed wafer is covered with 8,000 Å of high density plasma CVD silicon dioxide to produce a 6,000 Å pre-CMP Step Height (e.g., as shown in FIG. 1);

(b) CMP Polisher: Strasbaugh 6EC 8-inch wafer polisher with a Gimbal head suitable for holding the wafer;

(c) Polishing Pad: Rodel IC-1000 (K-grooved) pad with Suba-4 backing; and

(d) Pad Conditioner: Marshall 80 grit diamond disk.

3. Standard Polishing Conditions:

(a) For the Strasbaugh Polisher: 7 psi down pressure; 3 psi back pressure; 60 rpm rotation speed at the same direction for both polishing head and polishing table;

(b) For the Pad Conditioner: 60% in-situ; 50 rpm rotation speed; 6 pound down force; and

(c) Oxide CMP slurry composition flow rate: 150 ml/min.

4. Procedure

Oxide CMP slurry compositions are used to polish wafers using the materials and conditions described above. Polishing is stopped after a few seconds of polishing and measurements are taken at twenty-three radial locations across the wafers and averaged until a Minimum Step Height and End Point is determined. Once the End Point has been reached, polishing is permitted to continue for 20 seconds and successive Step Height Measurements are taken and averaged to determine the change in Step Height that occurs in successive 20-second intervals of Over Polishing after the End Point.

Conventional oxide CMP slurry compositions do increase the Minimum Step Height by more than 100 Å during the first 20 seconds of Over Polishing in accordance with the Standard Oxide CMP Testing Method. Oxide CMP slurry compositions according to the invention do not increase the Minimum Step Height by more than 100 Å during the first 20 seconds of Over Polishing in accordance with the Standard Oxide CMP Testing Method. More preferably, oxide CMP slurry compositions according to the invention do not increase the Minimum Step Height by more than 100 Å during the first 40 or more seconds of Over Polishing in accordance with the Standard Oxide CMP Testing Method.

The following examples are intended only to illustrate the invention and should not be construed as imposing limitations upon the claims.

### EXAMPLE 1

Oxide CMP Slurry Compositions A, B and C were prepared by dispersing the amounts, by weight, of the various constituents shown in Table 1 below in deionized, distilled (DI) water. Oxide CMP Slurry Composition A contained proline, but did not contain any polyvinyl pyrrolidone. Oxide CMP Slurry Composition B contained polyvinyl pyrrolidone, but did not contain any proline. Oxide CMP Slurry Composition C contained both proline and polyvinyl pyrrolidone and is thus the only oxide CMP slurry composition in Example 1 that can be properly considered as an oxide CMP slurry composition according to the invention. A sufficient amount of nitric acid was added to each slurry composition to reduce the pH to 4.

TABLE 1

| Constituent | SLURRY A | | SLURRY B | | SLURRY C | |
|---|---|---|---|---|---|---|
| Proline | 2.0 | wt % | — | | 1.5 | wt % |
| Polyvinyl pyrrolidone | — | | 2.0 | wt % | 0.2 | wt % |
| Ceria particles (Dₘₑₐₙ = | 4.0 | wt % | 4.0 | wt % | 4.0 | wt % |
| 0.13 μm) | | | | | | |
| PPO/PEO block copolymer | 0.4 | wt % | 0.4 | wt % | 0.4 | wt % |
| Glutaraldehyde | 0.05 | wt % | 0.05 | wt % | 0.05 | wt % |

Oxide CMP Slurry Compositions A, B and C were each separately used to polish processed wafers in accordance with the Standard Oxide CMP Testing Method previously described above. The results of the testing are shown in Table 2 below.

TABLE 2

| | SLURRY A | SLURRY B | SLURRY C |
|---|---|---|---|
| Minimum Step Height | 416 Å | 503 Å | 428 Å |
| Polishing Time to Achieve | 97 seconds | 60 seconds | 150 seconds |
| Minimum Step Height | | | |
| Step Height After 20 | 878 Å | 712 Å | 428 Å |
| Seconds of Over Polishing | | | |
| Increase in Step Height | 462 Å | 209 Å | 0 Å |
| Caused by 20 Seconds of | | | |
| Over Polishing | | | |
| Step Height After 40 Seconds | — | 1006 Å | 428 Å |
| of Over Polishing | | | |
| Increase in Step Height | — | 503 Å | 0 Å |
| Caused by 40 Seconds of | | | |
| Over Polishing | | | |
| Step Height After 60 Seconds | — | — | 428 Å |
| of Over Polishing | | | |
| Increase in Step Height | — | — | 0 Å |
| Caused by 60 Seconds of | | | |
| Over Polishing | | | |

Oxide CMP Slurry Compositions A and B, which did not contain the synergistic combination of proline and polyvinyl pyrrolidone, produced a significant (>100 Å) increase in Step Height as a result of a relatively short period (˜20 seconds) of Over Polishing beyond the End Point. Oxide CMP Slurry C, however, which contained the synergistic combination of proline and polyvinyl pyrrolidone, did not exhibit an appreciable increase in Step Height although Over Polishing continued for 60 seconds beyond the End Point (i.e., 210 seconds of polishing).

### EXAMPLE 2

Oxide CMP Slurry Compositions D and E were prepared by dispersing the amounts, by weight, of the various constituents shown in Table 3 below in deionized, distilled (DI) water. Oxide CMP Slurry Composition D contained N-octyl-2-pyrrolidone, but did not contain any proline. Oxide CMP Slurry Composition E contained both proline and N-octyl-2-pyrrolidone and is thus the only oxide CMP slurry composition in this Example that can be properly considered as an oxide CMP slurry composition according to the invention. Oxide CMP Slurry Composition A reported in Table 3 is from Example 1. A sufficient amount of nitric acid was added to each slurry composition to reduce the pH to 4.

TABLE 3

| Constituent | SLURRY A | | SLURRY D | | SLURRY E | |
|---|---|---|---|---|---|---|
| Proline | 2.0 | wt % | — | | 2.0 | wt % |
| N-octyl-2-pyrrolidone | — | | 0.04 | wt % | 0.04 | wt % |
| Ceria particles (Dₘₑₐₙ = | 4.0 | wt % | 4.0 | wt % | 4.0 | wt % |
| 0.13 μm) | | | | | | |
| PPO/PEO block copolymer | 0.4 | wt % | 0.4 | wt % | 0.4 | wt % |
| Glutaraldehyde | 0.05 | wt % | 0.05 | wt % | 0.05 | wt % |

Oxide CMP Slurry Compositions A, D and E were each separately used to polish processed wafers in accordance with the Standard Oxide CMP Testing Method previously described above. The results of the testing are shown in Table 4 below.

TABLE 4

| | SLURRY A | SLURRY D | SLURRY E |
|---|---|---|---|
| Minimum Step Height | 416 Å | 152 Å | 189 Å |
| Polishing Time to Achieve | 97 seconds | 100 seconds | 150 seconds |
| Minimum Step Height | | | |
| Step Height After 20 | 878 Å | 744 Å | 222 Å |
| Seconds of Over Polishing | | | |
| Increase in Step Height | 462 Å | 592 Å | 33 Å |
| Caused by 20 Seconds of | | | |
| Over Polishing | | | |
| Step Height After 40 Seconds | — | 949 Å | 264 Å |
| of Over Polishing | | | |
| Increase in Step Height | — | 797 Å | 75 Å |
| Caused by 40 Seconds of | | | |
| Over Polishing | | | |

Oxide CMP Slurry Compositions A and D, which did not contain the synergistic combination of proline and N-octyl-2-pyrrolidone, produced a significant (>100 Å) increase in Step Height as a result of a relatively short period (˜20 seconds) of Over Polishing beyond the End Point. Oxide CMP Slurry Composition E, however, which contained the synergistic combination of proline and N-octyl-2-pyrrolidone, did not increase the Minimum Step Height by more than 100 Å during the first 40 seconds of Over Polishing in accordance with the Standard Oxide CMP Testing Method.

Additional advantages and modifications will readily occur to those skilled in the art. Therefore, the invention in its broader aspects is not limited to the specific details and illustrative examples shown and described herein. Accordingly, various modifications may be made without departing from the spirit or scope of the general inventive concept as defined by the appended claims and their equivalents.

What is claimed is:

1. An oxide CMP slurry composition comprising:
a compound selected from the group consisting of proline, lysine and arginine;
a pyrrolidone compound; and
abrasive particles;
wherein the slurry composition does not increase a Minimum Step Height by more than 100 Å during the first 20 seconds of Over Polishing in accordance with the Standard Oxide CMP Testing Method.

2. The slurry according to claim 1 wherein the oxide CMP slurry composition comprises from about 0.2% to about 8% by weight of the compound selected from the group consisting of proline, lysine and arginine.

3. The slurry according to claim 1 wherein the oxide CMP slurry composition comprises from about 0.01% to about 10% by weight of the pyrrolidone compound.

4. The slurry according to claim 2 wherein the oxide CMP slurry composition comprises from about 0.01% to about 10% by weight of the pyrrolidone compound.

5. The slurry according to claim 1 wherein the pyrrolidone is selected from the group consisting of polyvinyl pyrrolidone, N-octyl-2-pyrrolidone, N-dodecyl-2-pyrrolidone, N-methyl-2-pyrrolidone, N-ethyl-2-pyrrolidone, N-hydroxyethyl-2-pyrrolidone, N-Cyclohexyl-2-pyrrolidone, N-butyl-2-pyrrolidone, N-hexyl-2-pyrrolidone, N-decyl-2-pyrrolidone, N-octadecyl-2-pyrrolidone, N-hexadecyl-2-pyrrolidone and copolymers of polyvinyl pyrrolidone, and combinations of the foregoing.

6. The slurry according to claim 1 wherein the abrasive particles comprise cerium atoms and have a mean average secondary particle size of from about 0.03 μm to about 0.30 μm.

7. The slurry according to claim 6 wherein the compound selected from the group consisting of proline, lysine and arginine, the pyrrolidone compound and the abrasive oxide particles comprising cerium atoms are dispersed in an aqueous medium.

8. The slurry according to claim 7 wherein the pH of the slurry is from about 3 to about 5.

9. The slurry according to claim 1 further comprising one or more optional additives selected from the group consisting of dispersing agents, preservative biocides, preservative fungicides, acids, bases and pH buffers.

10. An oxide CMP slurry composition comprising:
proline;
a pyrrolidone compound; and
abrasive particles;
wherein the slurry composition does not increase a Minimum Step Height by more than 100 Å during the first 20 seconds of Over Polishing in accordance with the Standard Oxide CMP Testing Method.

11. The slurry according to claim 10 wherein the oxide CMP slurry composition comprises from about 0.2% to about 8% by weight of proline.

12. The slurry according to claim 10 wherein the oxide CMP slurry composition comprises from about 0.01% to about 10% by weight of the pyrrolidone compound.

13. The slurry according to claim 11 wherein the oxide CMP slurry composition comprises from about 0.01% to about 10% by weight of the pyrrolidone compound.

14. The slurry according to claim 10 wherein the pyrrolidone compound is a non-polymeric pyrrolidone compound.

15. The slurry according to claim 14 wherein the pyrrolidone compound is N-octyl-2-pyrrolidone.

16. The slurry according to claim 10 wherein the slurry composition does not increase a Minimum Step Height by more than 100 Å during the first 40 seconds of Over Polishing in accordance with the Standard Oxide CMP Testing Method.

17. A method of fabricating a CMOS device comprising:
providing a processed wafer comprising a semiconductor substrate having a thermal oxide layer grown thereon and a silicon nitride stop layer formed on the oxide layer, wherein the silicon nitride stop layer, thermal oxide layer and the substrate have been patterned using a photoresist and etch back process to create field areas and active areas, wherein the field areas are defined by a trench where etching has occurred, and wherein the field areas are filled with silicon dioxide and the active areas are covered with the silicon nitride stop layer and a silicon dioxide overburden;
providing an oxide CMP slurry composition comprising:
one or more selected from the group consisting of proline, lysine and arginine; and
a pyrrolidone compound;
disposing the oxide CMP slurry composition between a polishing pad and the processed wafer; and
polishing the processed wafer with the polishing pad to remove the silicon dioxide overburden.

18. The method according to claim 17 wherein the oxide CMP slurry composition comprises from about 0.2% to about 8% by weight of the compound selected from the group consisting of proline, lysine and arginine.

19. The method according to claim 17 wherein the oxide CMP slurry composition comprises from about 0.01% to about 10% by weight of the pyrrolidone compound.

20. The method according to claim 18 wherein the oxide CMP slurry composition comprises from about 0.01% to about 10% by weight of the pyrrolidone compound.

21. The method according to claim 17 wherein the compound selected from the group consisting of proline, lysine and arginine, and the pyrrolidone compound are dispersed in an aqueous medium together with abrasive particles.

22. The method according to claim 21 wherein the average particle size of the abrasive particles is from about 0.03 μm to about 0.30 μm.

23. The method according to claim 17 wherein the oxide CMP slurry composition comprises proline and a non-polymeric pyrrolidone compound.

24. The method according to claim 23 wherein the oxide CMP slurry composition further comprises abrasive particles comprising cerium atoms dispersed in a liquid medium.

25. The method according to claim 23 wherein abrasive particles comprising cerium atoms are bonded to the polishing pad, and the abrasive particles become dispersed in a liquid medium during polishing.
